(19) United States
(12) Patent Application Publication
(10) Pub. No.: US 2009/0121801 A1
(43) Pub. Date: May 14, 2009

(54) PULSE WIDTH MODULATION DRIVING DEVICE

(75) Inventor: Kai-Hsu CHENG, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: BEYOND INNOVATION TECHNOLOGY CO., LTD., Taipei (TW)

(21) Appl. No.: 12/201,181

(22) Filed: Aug. 29, 2008

(30) Foreign Application Priority Data
Nov. 8, 2007 (TW) 96142215

(51) Int. Cl. H03K 7/08

(52) U.S. Cl. 332/109

(57) ABSTRACT

A pulse width modulation (PWM) driving device for generating a driving signal to a load is provided. A driving unit provides the driving signal according to a PWM signal and a control signal. A pulse generating unit generates the PWM signal according to a feedback signal from the load. A control unit generates the control signal according to an enable signal and the feedback signal. The control unit generates the control signal to control the driving unit to stop outputting the driving signal when the enable signal is at a first logic level and the feedback signal is smaller than a first predetermined voltage during a first time interval. The control unit generates a reset signal to reset the driving unit and the pulse generating unit when the enable signal is at a second logic level during a second time interval.

### CROSS REFERENCE TO RELATED APPLICATIONS

This application claims the benefit of Taiwan Patent Application No. 096142215, filed Nov. 8, 2007, the entirety of which is incorporated by reference herein.

### BACKGROUND OF THE INVENTION

1. Field of the Invention

The invention relates to a pulse width modulation (PWM) driving device, and more particularly, to a PWM driving device with over voltage protection and under voltage protection.

2. Description of the Related Art

In light emitting diode (LED) applications, a driving device which outputs a pulse width modulation (PWM) signal is usually used to drive the LED. In general, the driving device generates a driving signal to the LED and determines whether the LED is normal by detecting a feedback signal from the LED. The driving device will enable/perform an over voltage protection when the feedback signal has a higher voltage, and the driving device will enable/perform a under voltage protection when the feedback signal has a lower voltage.

The driving device is usually operated in an ON/OFF mode. For example, the driving device may output the PWM signal when an enable signal of the driving device is at a high logic level. In contrast, the driving device may stop outputting the PWM signal when the enable signal is at a low logic level. However, if the driving device is operated in a dimming control mode, the enable signal is a pulse signal. Hence, for a driving device, generating a driving signal and enabling the over voltage protection and under voltage protection are complex.

### BRIEF SUMMARY OF THE INVENTION

A pulse width modulation (PWM) driving device is provided, wherein the PWM driving device generates a driving signal to a load. An embodiment of a PWM driving device comprises a driving unit, a pulse generating unit and a control unit. The driving unit provides the driving signal according to a pulse width modulation signal and a control signal. The pulse generating unit generates the pulse width modulation signal according to a feedback signal from the load. The control unit generates the control signal according to an enable signal and the feedback signal. The control unit generates the control signal to the driving unit to stop outputting the driving signal when the enable signal is at a first logic level and the feedback signal is smaller than a first predetermined voltage during a first time interval. The control unit generates a reset signal to reset the driving unit and the pulse generating unit when the enable signal is at a second logic level during a second time interval.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a pulse width modulation (PWM) driving system according to an embodiment of the invention;

FIG. 2 shows a control unit according to an embodiment of the invention;

FIGS. 3A and 3B show a waveform diagram of the embodiment illustrated in FIG. 2, respectively; and

FIG. 4 shows a control unit according to another embodiment of the invention; and

FIG. 5 shows a control unit according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

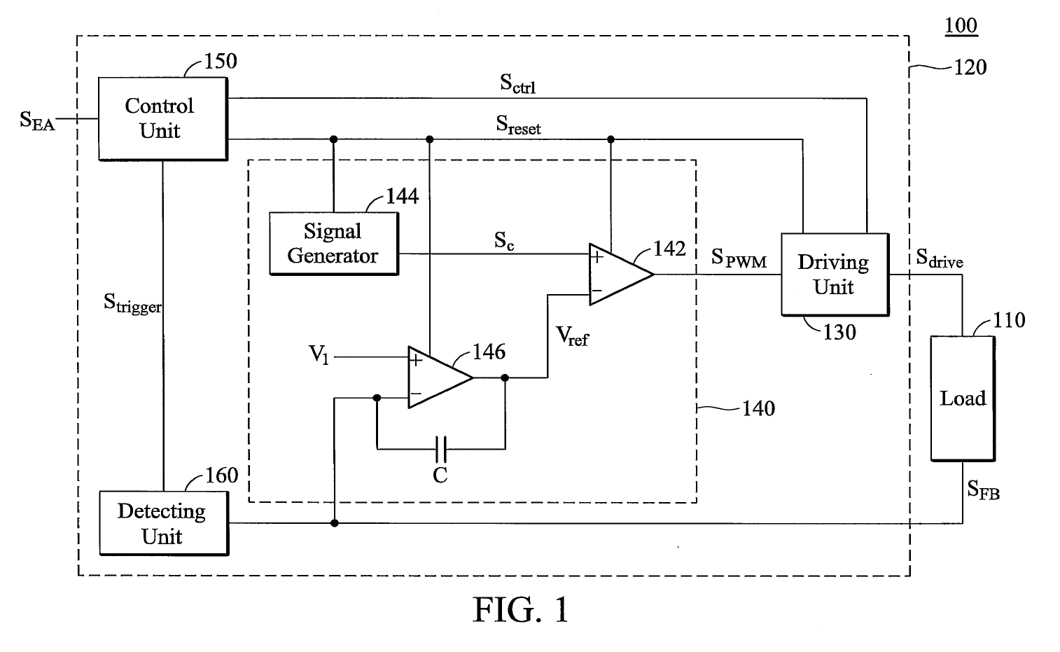

FIG. 1 shows a pulse width modulation (PWM) driving system 100 according to an embodiment of the invention. The PWM driving system 100 of this embodiment comprises a load 110 and a PWM driving device 120, wherein the PWM driving device 120 generates a driving signal S_{drive} to the load 110 according to an enable signal S_{EA} and receives a feedback signal S_{FB} from the load 110 to detect an operating state of the load 110. For example, the PWM driving device 120 is activated to generate the driving signal S_{drive} when the enable signal S_{EA} is at a high logic level. Furthermore, the enable signal S_{EA} may be a pulse signal. Moreover, the driving signal S_{drive} may be boosted by a DC/DC converter and if so, then the boosted driving signal S_{drive} is transmitted to the load 110.

As shown in FIG. 1, the PWM driving device 120 comprises a driving unit 130, a pulse generating unit 140, a control unit 150 and a detecting unit 160. The driving unit 130 provides the driving signal S_{drive} to the load 110 according to a PWM signal S_{PWM}. The pulse generating unit 140 comprises a comparator 142, a signal generator 144 and an amplifier 146. The signal generator 144 generates a signal S_{c} to a non-inverting input of the comparator 142. In this embodiment, the signal S_{c} is a ramp signal. The amplifier 146 generates a reference voltage V_{ref} to an inverting input of the comparator 142 according to the feedback signal S_{FB} and a voltage V₁. Next, by comparing the signal S_{c} and the reference voltage V_{ref}, the comparator 142 generates the PWM signal S_{PWM} to the driving unit 130. Then, the driving unit 130 may decide to output the driving signal S_{drive} or not according to a control signal S_{ctrl}. In this embodiment, the amplifier 146 is an error amplifier, and the load 110 is a light emitting diode (LED).

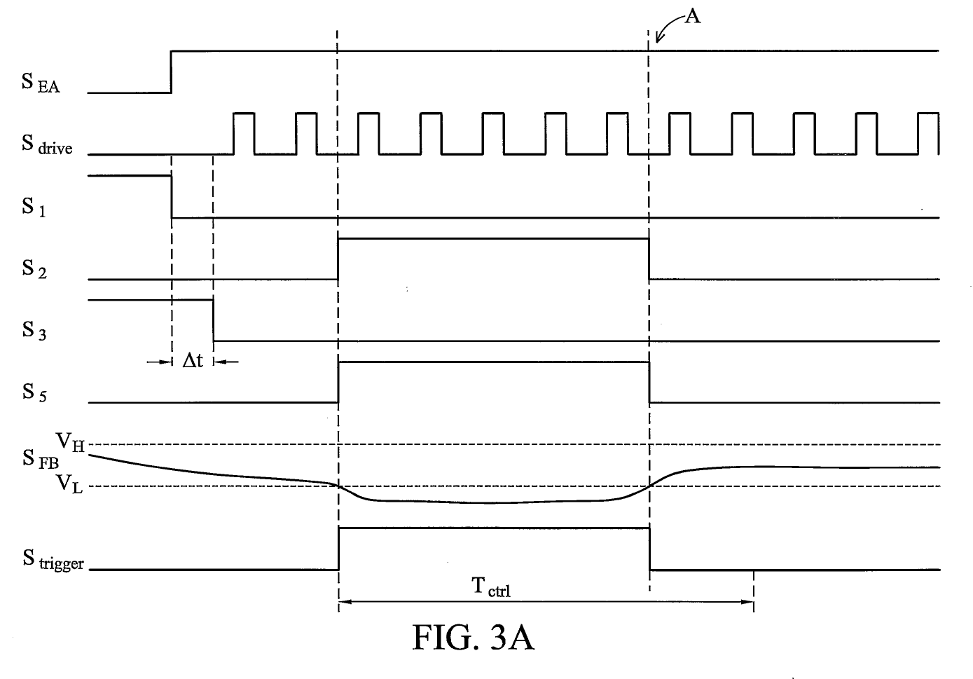

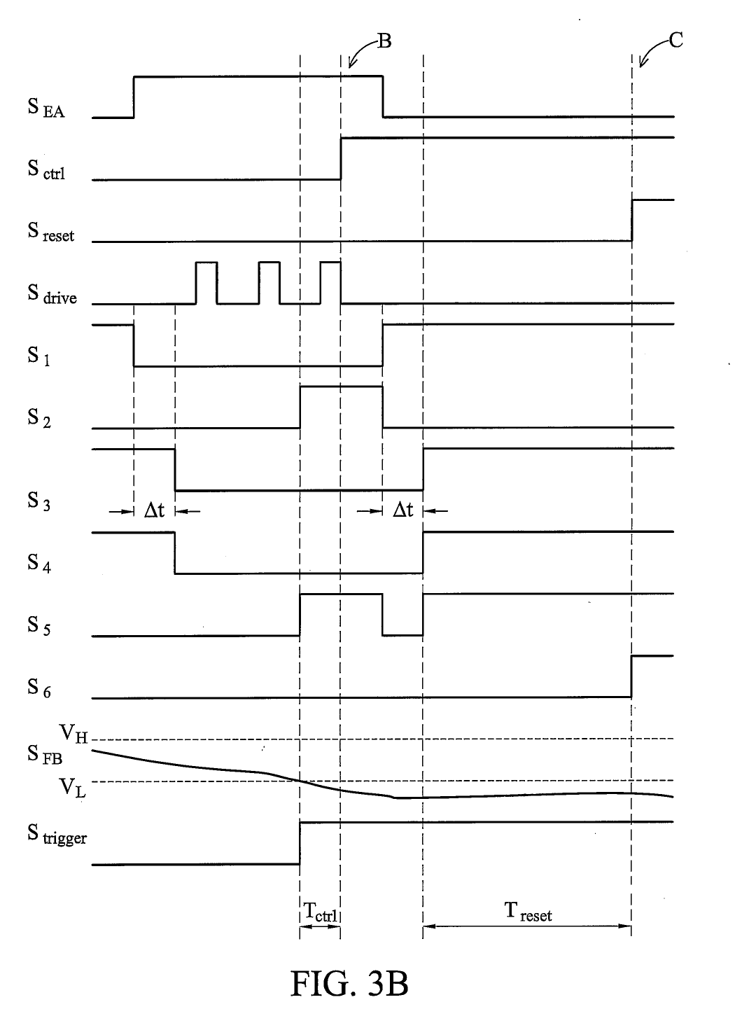

Referring to FIG. 1 and FIG. 3A together, the detecting unit 160 may generate a trigger signal S_{trigger} to the control unit 150 when a voltage of the feedback signal S_{FB} is smaller than a voltage V_{L} (for example 0.25V). According to the trigger signal S_{trigger}, the control unit 150 may determine that the operating state of the load 110 is abnormal. For example, the trigger signal S_{trigger} is at a high logic level when the voltage of the feedback signal S_{FB} is smaller than the voltage V_{L}; otherwise, the trigger signal S_{trigger} is at a low logic level. The control unit 150 may generate the control signal S_{ctrl} and a reset signal Sᵣₑₛₑₜ according to the enable signal S_{EA} and the trigger signal S_{trigger}, wherein the reset signal Sᵣₑₛₑₜ may reset the units of the PWM driving device 120, such as the driving unit 130, the pulse generating unit 140 or the detecting unit 160 etc. In this embodiment, the reset signal Sᵣₑₛₑₜ may disable the all functions of the units in the PWM driving device 120.

In the PWM driving device 120, the control unit 150 may generate the reset signal Sᵣₑₛₑₜ to other units when the enable signal S_{EA} is maintained at a low logic level during a time interval Tᵣₑₛₑₜ, for example ₂₀ ms, wherein the time interval Tᵣₑₛₑₜ is determined/selected according to different applications of the load 110. It is to be noted, if the enable signal S_{EA} is a pulse signal, a time interval of the enable signal S_{EA} maintained at a low logic level must be shorter than the time interval Tᵣₑₛₑₜ.

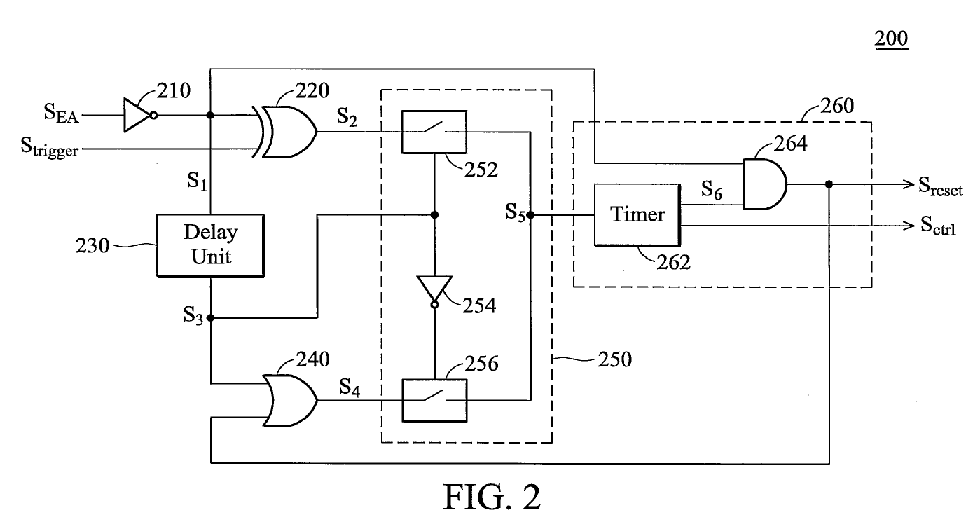

FIG. 2 shows a control unit 200 according to an embodiment of the invention. The control unit 200 comprises an inverter 210, an exclusive-OR (XOR) gate 220, a delay unit 230, an OR gate 240, a selecting unit 250 and a counting time unit 260. The selecting unit 250 comprises an inverter 254 and two switches 252 and 256. The selecting unit 250 selects a signal S₂ or a signal S₄ as a signal S₅ according to a signal S₃. In this embodiment, if the enable signal S_{EA} is at a low logic level, the switch 252 is turned on during a delay time Δt generated by the delay unit 230. After the delay time Δt has passed, the switch 256 is turned on to control a timer 262. The counting time unit 260 comprises the timer 262 and an AND gate 264. In this embodiment, the timer 262 starts to count time when the signal S₅ which is at a high logic level is received.

Referring to FIG. 2 and FIG. 3A together, first, the enable signal S_{EA} is changed from a low to high logic level to start the control unit 200 in a PWM driving device (as shown in the PWM driving device of FIG. 1). In the control unit 200, the inverter 210 receives the enable signal S_{EA} to generate the signal S₁, which is at a low logic level. Next, the delay unit 230 delays the signal S₁ to generate the signal S₃, wherein a delay time between the signal S₁ and the signal S₃ is adjusted according to different applications. The switch 252 is turned on and the switch 256 is turned off as the signal S₃ is at a low logic level. Next, the trigger signal S_{trigger} is changed from a low to high logic level when the voltage of the feedback signal S_{FB} is smaller than the voltage V_{L}. Next, the signal S₂ and the signal S₅ are also changed from a low to high logic level. Because the signal S₅ is at a high logic level, the timer 262 will start to count time. If the trigger signal S_{trigger} is changed to a low logic level (i.e. the voltage of the feedback signal S_{FB} is greater than or equal to the voltage V_{L}) and a time interval T_{ctrl} (for example 0.5 ms) counted by the timer 262 has not been reached, the signal S₅ is changed to a low logic level and the timer 262 may stop counting time, as shown in the arrow A of FIG. 3A. In contrast, if the trigger signal S_{trigger} is maintained at a high logic level and the time interval T_{ctrl} counted by the timer 262 has been reached, the timer 262 may output the control signal S_{ctrl} with a high logic level to the driving unit 130 in FIG. 1 to stop outputting the driving signal S_{drive}, as shown in the arrow B of FIG. 3B. Therefore, referring back to FIG. 1, the PWM driving device 120 may perform an under voltage protection for the load 110 until the control unit 150 sends the reset signal Sᵣₑₛₑₜ. In this embodiment, if the voltage of the feedback signal S_{FB} is greater than a voltage V_{H} (for example 1.5V), the detecting unit 160 also generates the trigger signal S_{trigger}, which is at a high logic level so as to enable an over voltage protection and stop outputting the driving signal S_{drive}. In one embodiment, a time interval T_{ctrl} which is counted for enabling an over voltage protection is smaller than a time interval T_{ctrl} which is counted for enabling a under voltage protection.

Next, referring to FIG. 2 and FIG. 3B together, after outputting the driving signal S_{drive}, has stopped, the signal S₁ is changed to a high logic level when the enable signal S_{EA} is changed from a high to low logic level. Next, the signal S₂ and the signal S₅ are changed from a high to low logic level. Thus, the switch 252 is still turned on during the delay time Δt, and the timer 262 stops to count time because the signal S₅ is at a low logic level. Next, after the delay time Δt provided by the delay unit 230 has passed, the signal S₃ and the signal S₄ are changed to a high logic level. Thus, the switch 252 is turned off and the switch 256 is turned on because the signal S₃ is at a high logic level. Next, the signal S₅ is changed from a low to high logic level and the timer 262 may start to count time. If the enable signal S_{EA} is maintained at a low logic level and the time interval Tᵣₑₛₑₜ counted by the timer 262 has been reached, the timer 262 may output a signal S₆ to the AND gate 264, as shown in the arrow C of FIG. 3B. Next, the AND gate 264 generates the reset signal Sᵣₑₛₑₜ according to the signal S₆ and the signal S₁ to reset (or re-start) other units of the PWM driving device and disable the over voltage protection or the under voltage protection, wherein the reset signal Sᵣₑₛₑₜ is at a high logic level. In the embodiment, the time interval Tᵣₑₛₑₜ is greater than the time interval T_{ctrl}.

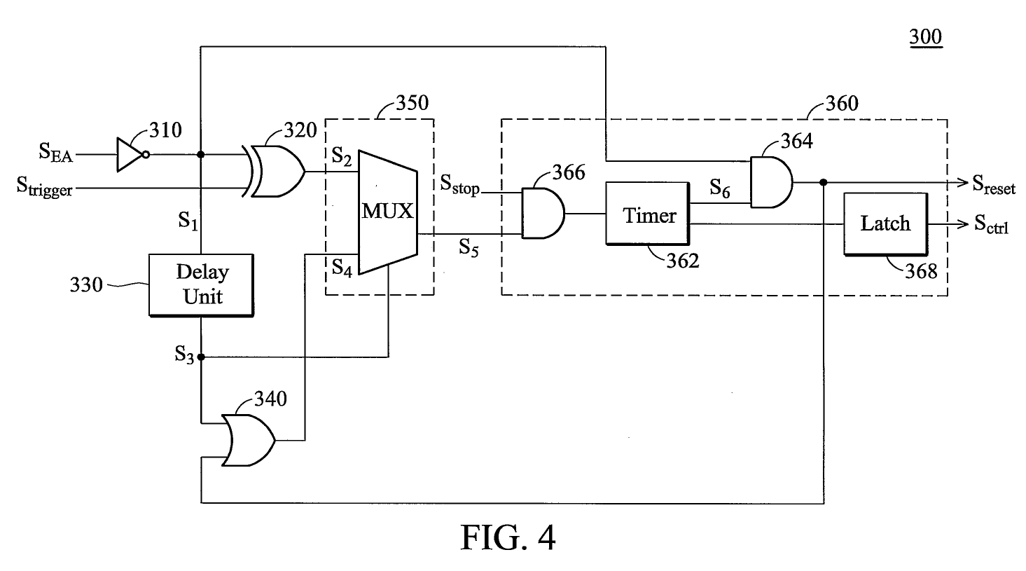

FIG. 4 shows a control unit 300 according to another embodiment of the invention. In FIG. 4, a selecting unit 350 is formed with a multiplexer, which may select the signal S₂ or the signal S₄ as the signal S₅ according to the signal S₃. Furthermore, a counting time unit 360 comprises a timer 362, an AND gate 364, an AND gate 366 and a latch 368, wherein the latch 368 is used to store the control signal S_{ctrl}. Moreover, excluding the signal S₅, the counting time unit 360 may also determine to count time or not according to a signal Sₛₜₒₚ, wherein the signal Sₛₜₒₚ may be set by a user or may be generated by other detecting circuits. For example, the signal Sₛₜₒₚ is at a low logic level when an operating voltage of the PWM driving device is abnormal and the signal Sₛₜₒₚ is changed to a high logic level until the operating voltage is normal.

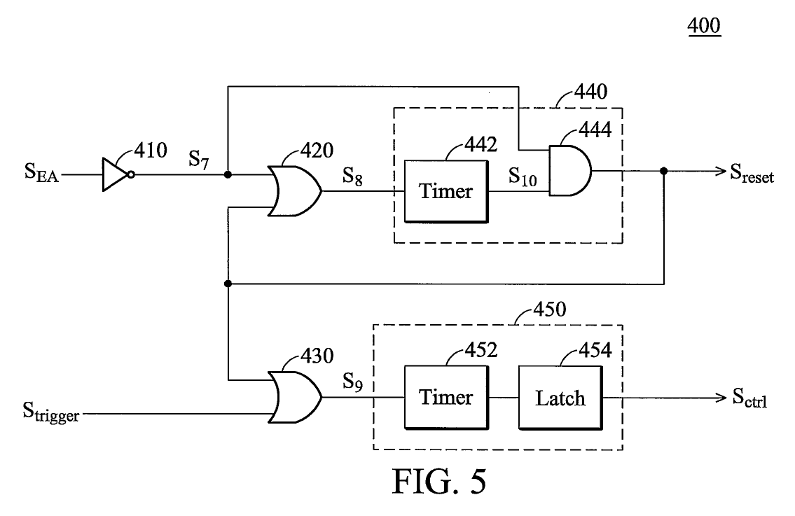

FIG. 5 shows a control unit 400 according to another embodiment of the invention. In the control unit 400, the time interval Tᵣₑₛₑₜ and the time interval T_{ctrl} are counted by different timers, respectively. The control unit 400 comprises an inverter 410, an OR gate 420, an OR gate 430, a counting time unit 440 and a counting time unit 450. The counting time unit 440 comprises a timer 442 and an AND gate 444, and the counting time unit 450 comprises a timer 452 and a latch 454. First, when the enable signal S_{EA} is at a high logic level, a signal S₇ is at a low logic level such that the reset signal Sᵣₑₛₑₜ is at a low logic level. Next, the trigger signal S_{trigger} is changed from a low to high logic level when the voltage of the feedback signal S_{FB} is smaller than the voltage V_{L} or the voltage of the feedback signal S_{FB} is greater than the voltage V_{H}. If the reset signal Sᵣₑₛₑₜ is at a low logic level and the trigger signal S_{trigger} is at a high logic level, the OR gate 430 may generate a signal S₉ with a high logic level. Thus, the timer 452 then starts to count time because the signal S₉ is at a high logic level. The timer 452 may stop counting time when the trigger signal S_{trigger} is changed to a low logic level and the time interval T_{ctrl} counted by the timer 452 has not been reached. In contrast, if the trigger signal S_{trigger} is still at a high logic level and the time interval T_{ctrl} counted by the timer 452 has been reached, the counting time unit 450 may output the control signal S_{ctrl} to the driving unit to stop outputting the driving signal S_{drive}. Moreover, after outputting the driving signal S_{drive} has stopped, the signal S₇ is changed to a high logic level when the enable signal S_{EA} is changed from a high to low logic level. Next, a signal S₈ is changed from a low to high logic level. Because the signal S₈ is at a high logic level, the timer 442 starts to count time. If the enable signal S_{EA} is changed to a high logic level and the time interval Tᵣₑₛₑₜ counted by the timer 442 has not been reached, the timer 442 may stop counting time. In contrast, if the enable signal S_{EA} is still at a low logic level and the time interval reset counted by the timer 442 has been reached, the counting time unit 440 may output the reset signal Sᵣₑₛₑₜ with a high logic level to reset other units of the PWM driving device and disable the over voltage protection or the under voltage protection.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A pulse width modulation (PWM) driving device for generating a driving signal to a load, comprising:
a driving unit providing the driving signal according to a pulse width modulation signal and a control signal;
a pulse generating unit generating the pulse width modulation signal according to a feedback signal from the load; and
a control unit generating the control signal according to an enable signal and the feedback signal, wherein the control unit generates the control signal to the driving unit to stop outputting the driving signal when the enable signal is at a first logic level and the feedback signal is smaller than a first predetermined voltage during a first time interval, and the control unit generates a reset signal to reset the driving unit and the pulse generating unit when the enable signal is at a second logic level during a second time interval.

2. The pulse width modulation driving device as claimed in claim 1, wherein the pulse generating unit comprises:
a signal generator generating a ramp signal;
an amplifier generating a reference voltage according to a second predetermined voltage and the feedback signal; and
a comparator generating the pulse width modulation signal according to the ramp signal and the reference voltage.

3. The pulse width modulation driving device as claimed in claim 1, further comprising a detecting unit, wherein the detecting unit generates a trigger signal when the feedback signal is smaller than the first predetermined voltage.

4. The pulse width modulation driving device as claimed in claim 1, wherein the enable signal is a pulse signal.

5. The pulse width modulation driving device as claimed in claim 1, wherein the first time interval is smaller than the second time interval.

6. The pulse width modulation driving device as claimed in claim 3, wherein the control unit comprises:
an inverter receiving the enable signal to generate a first signal;
an exclusive-OR (XOR) gate receiving the first signal and the trigger signal to generate a second signal;
a delay unit delaying the second signal to generate a third signal;
an OR gate receiving the third signal and the reset signal to generate a fourth signal;
a selecting unit selecting the second signal or the fourth signal to output a fifth signal according to the third signal; and
a counting time unit counting time to generate the reset signal and the control signal according to the first signal and the fifth signal.

7. The pulse width modulation driving device as claimed in claim 6, wherein the control signal is generated when the first time interval counted by the counting time unit has been reached, and the reset signal is generated when the second time interval counted by the counting time unit has been reached.

8. The pulse width modulation driving device as claimed in claim 6, wherein the selecting unit comprises a switch or a multiplexer.

9. The pulse width modulation driving device as claimed in claim 6, wherein the counting time unit comprises:
a timer counting time to generate a sixth signal and the control signal according to the fifth signal; and
an AND gate receiving the first signal and the sixth signal to generate the reset signal.

10. The pulse width modulation driving device as claimed in claim 9, wherein the counting time unit further comprises a latch for storing the control signal.

11. The pulse width modulation driving device as claimed in claim 9, wherein the timer stops counting time according to a stop signal.

12. The pulse width modulation driving device as claimed in claim 3, wherein the control unit comprises:
an inverter receiving the enable signal to generate a seventh signal;
a first OR gate receiving the seventh signal and the reset signal to generate an eighth signal;
a second OR gate receiving the trigger signal and the reset signal to generate a ninth signal;
a first counting time unit counting time to generate the control signal according to the ninth signal; and
a second counting time unit counting time to generate the reset signal according to the seventh signal and the eighth signal.

13. The pulse width modulation driving device as claimed in claim 12, wherein the control signal is generated when the first time interval counted by the first counting time unit has been reached, and the reset signal is generated when the second time interval counted by the second counting time unit has been reached.

14. The pulse width modulation driving device as claimed in claim 12, wherein the first counting time unit comprises:
a timer counting time to generate a tenth signal according to the eighth signal; and
an AND gate receiving the seventh signal and the tenth signal to generate the reset signal

15. The pulse width modulation driving device as claimed in claim 12, wherein the second counting time unit comprises a latch for storing the control signal.

16. The pulse width modulation driving device as claimed in claim 1, wherein the control unit generates the control signal to the driving unit to stop outputting the driving signal when the enable signal is at the first logic level and the feedback signal is greater than a third predetermined voltage during a third time interval.

17. The pulse width modulation driving device as claimed in claim 1, wherein the load is a light emitting diode.
